(19) United States
(12) Patent Application Publication
(10) Pub. No.: US 2001/0020578 A1
(43) Pub. Date: Sep. 13, 2001

(54) Touch contact switch with a LCD display

(76) Inventor: Martin Baier, Ettlingen (DE)

Correspondence Address: J. Rodman Steele, Jr., Akerman, Senterfitt & Eidson, P.A., Post Office Box 3188, West Palm Beach, FL, 33402-3188, US

(21) Appl. No.: 09/802,433

(22) Filed: Mar. 9, 2001

(30) Foreign Application Priority Data
Mar. 10, 2000 (DE) 10011645.0

(51) Int. Cl. H03K 17/975

(52) U.S. Cl. 200/600

(57) ABSTRACT

The invention provides an embodiment of a touch contact switch with a LC display or LCD (11, 26) having two parallel, superimposed glass plates (12, 13), between which are located conductive layers (15, 16; 27, 28) provided with terminals (29) for displaying individual segments (24, 25) of the LCD. According to the invention, below the surface (14) of the LCD is provided at least one sensor element (19; 21, 22) of the touch contact switch, which is operable by contacting the surface of the LCD above the sensor element. For this purpose on the one hand known sensor elements (19; 21, 22) of touch contact switches can be placed under the LCD and on the other portions of the conductive layers (27, 28) can be activated in interval operation both for displaying LCD symbols (24) and as sensor surfaces of capacitive touch contact switches.

The invention relates to a touch contract switch or touch contact switch unit, particularly for an electrical appliance, having a LC display, which has at least two parallel, superimposed plates, between which are positioned conductive layers or layer portions provided with terminals for the representation or display of individual segments of the LCD. A liquid crystal is located between the layers. A polarizing filter is advantageously fitted to the front plate. Below the lower plate is either provided a back lighting and a polarizing filter (transmissive type) or a reflective layer (reflective type). For displaying the segments the conductive layers can be activated in the conventional manner from the outside by means of the terminals (antipole for the display of a segment by means of a dark surface).

LCDs are used in many fields for displaying information, e.g. in small format in watches or in larger format in displays of electrical appliances or notebook screens. The LCD e.g. shows a state which is variable at random by means of switches or the like on the appliance.

### PROBLEM AND SOLUTION

The problem of the invention is to provide a touch contact switch of the aforementioned type permitting a combination of a LCD and a touch contact switch.

This problem is solved by a touch contact switch having the features of claim 1. Advantageous developments of the invention form the subject matter of the further claims and are described hereinafter.

According to the invention below the surface of the LCD is provided at least one sensor element of the touch contact switch, which is operable by contacting the surface of the LCD above the sensor element. This provides the possibility by means of a single built-in module, which can be prefabricated, to provide both a display and a switch unit. It is advantageously also possible by the display with the LCD segments to display the precise position of the touch contact switch, e.g. for “+” or “−” displays or the direct operation of an “off” zone. Such displays can be incorporated into electrical appliances and serve both as function displays and as operating zones similar to switches. As a further example remote controls and the like can be equipped with large displays and different displays display function states of the appliance. Through the operation of the associated sensor elements or touch contact switches by placing a finger on the display surface it is possible to modify said function state. Both the display of function states and the associated switching function can be varied, e.g. split up into several subfunctions.

According to an embodiment the at least one sensor element can be located in the vicinity of the LCD segments. Particular suitability is provided by an area between different segments or within an open segment, which e.g. displays the contact zone like a frame.

It is possible to place the at least one sensor element below the lower plate. However, it is preferably constructed separately thereof and is separable, so that standard components can be used.

According to one possibility the touch contact switch can have a reflected light barrier as the sensor element with a light transmitter and a light receiver. Advantageously the reflected light barrier can be positioned without taking account of the arrangement of the LCD conductive layers. It must merely be borne in mind that a represented segment would interfere with the light path, so that no segment should be located in the latter. The use of IR light is particularly appropriate. To save power and avoid interference by light scattered in from the outside, the reflected light barrier can be operated at intervals and in particular the transmitter and receiver operate on an interval basis.

According to a fundamentally different embodiment the sensor element can be constructed as a capacitive sensor element. It can be in the form of a flexible, conductive foam body, e.g. a foam cylinder. Such a sensor element is to be positioned at a point of the LCD without segments or conductive layer above the same. The foam body surface applied to the lower display plate acts as a capacitor plate of a capacitive sensor element. The operation of such sensor elements is adequately known.

According to another embodiment of a capacitive sensor element a conductive sensor layer or sensor layer portion can be placed between the plates or on one of the insides of the plates of the LCD in the form of a sensor surface. Thus, the sensor element is not only functionally, but also completely integrated into the LCD. Preferably the sensor layer is in the plane of one of the two conductive layers of the LCD and can be in the form of a separately applied layer. In particularly preferred manner the sensor layer or layer portion can be formed by one of the two conductive layers of the LCD and is electrically isolated from the layer areas required for displaying the segments.

According to another embodiment of the invention the sensor layer is formed by a portion of at least one of the two conductive layers in an area or by a portion usable for segment display purposes. The LCD can be activated in alternating manner with at least two operating modes. By means of the terminals the conductive layers are on the one hand operated in antipole manner for segment display and on the other separately or advantageously in short-circuited manner as a sensor element. Thus, a segment display takes place in alternating manner with the sensor element function. The alternation is to take place so rapidly that the human eye perceives a permanent segment representation, e.g. with a frequency of over 50 Hz up to a few hundred Hz. The conductive layers can be activated with an alternating current, particularly with a frequency of 30 to 100 kHz for the sensor element function.

These and further features can be gathered from the claims, description and drawings and the individual features, both singly and in the form of subcombinations, can be implemented in an embodiment of the invention and in other fields and can represent advantageous, independently protectable constructions for which protection is hereby claimed. The subdivision of the application into individual sections and the subheadings in no way restricts the general validity of the statements made thereunder.

### BRIEF DESCRIPTION OF THE DRAWINGS

Embodiments of the invention are described in greater detail hereinafter relative to the attached drawings, wherein show:

FIG. 1 A section through a LCD with a reflected light barrier and foam sensor element positioned below it.

FIG. 2 A plan view of an LCD according to FIG. 1.

FIG. 3 A section through a LCD with layer portions also operated as a sensor element for segment display purposes.

FIG. 4 A plan view of a LCD according to FIG. 3.

### DETAILED DESCRIPTION OF EMBODIMENTS

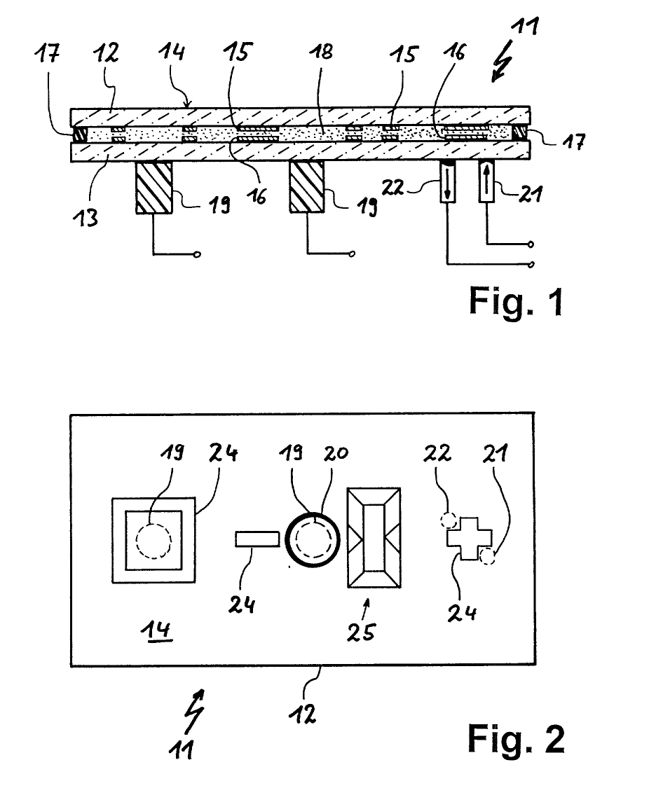

FIG. 1 shows in section a LC display or LCD 11, which has an upper glass plate 12 and a lower glass plate 13. In place of glass plates it is also possible to use transparent materials, e.g. plastic. Between the glass plates 12 and 13 is located an upper, conductive layer 15 and a lower, conductive layer 16, which are subdivided into individual portions. With regards to the contours this subdivision corresponds to the LCD symbols to be represented or displayed, cf. FIG. 2. Laterally the glass plates 12 and 13 are joined by a bond 17. Between the glass plates and also between the layers 15 and 16 is located a liquid crystal 18. This constitutes the basic construction of a LCD.

With respect to the contours the lower, conductive layer 16 can differ or can be larger than the upper layer 15. However, it must be borne in mind that at least the portions of the upper layer must be covered, but the terminals for the upper layer must not be covered. A layout for the two layers 15 and 16 can be similar to a printed circuit board layout.

Generally at the front on surface 14 is provided a polarizing filter, but the latter has been omitted here to facilitate understanding of the drawing. In addition, behind the lower glass plate 13, a conventional LCD either has a reflective layer or a back lighting and a polarizing filter, but these have also been omitted here.

To the left below the LCD 11 and applied to the underside of the lower glass plate 13 are two foam sensor elements 19 made from conductive foam. Foam sensor elements of this type are e.g. described in DE 197 06 168. The face of the sensor element 19 engaging on the glass plate forms the otherwise conventional, conductive surface of a capacitive sensor element. The control and evaluation are not shown, but can be gathered from the aforementioned patent application.

The two sensor elements 19 are positioned in such a way that no portion of the upper, conductive layer 15 or lower conductive layer 16 passes above them. This would put the capacitive sensor elements out of operation, because no electrical field lines could form above the sensor element. In addition, no terminals for the layer portions must pass above them. A non-metallic reflective layer generally causes no interference.

On the right hand side and below the LCD is provided a light transmitter 21 and a light receiver 22 based on the reflected light barrier principle. The light transmitter 21 emits light, preferably in the IR range. By the application of a finger above the same part of the light is reflected downwards and is collected by the light receiver 22 and evaluated for tripping the touch contact switch. The arrangement of the reflected light barrier is fundamentally independent of the conductive layers, but there must be no LCD symbol in the light path between transmitter and receiver. This is only possible if the light can pass through the LCD symbol, e.g. in the case of a suitable wavelength.

FIG. 2 shows the LCD 11 of FIG. 1 in plan view. It can be seen that the left-hand sensor element 19 is below a LCD zone 24. Optionally as a function of the situation, the LCD zone 24 can indicate the operation of this sensor element by the application of a finger to the surface 14 of the upper glass plate 12. The right-hand sensor element 19 is placed under a marking 20 applied to the surface 14.

The reflected light barrier formed by the transmitter and receiver 21, 22 is placed in sloping apart manner below a LCD zone 24 in the form of a plus sign. Thus, if an operation is to take place in high-order manner, it is possible to directly operate the plus sign 24 or place a finger thereon. Between the same is shown a conventional LCD digit 25, whose value can e.g. be changed by the plus sign.

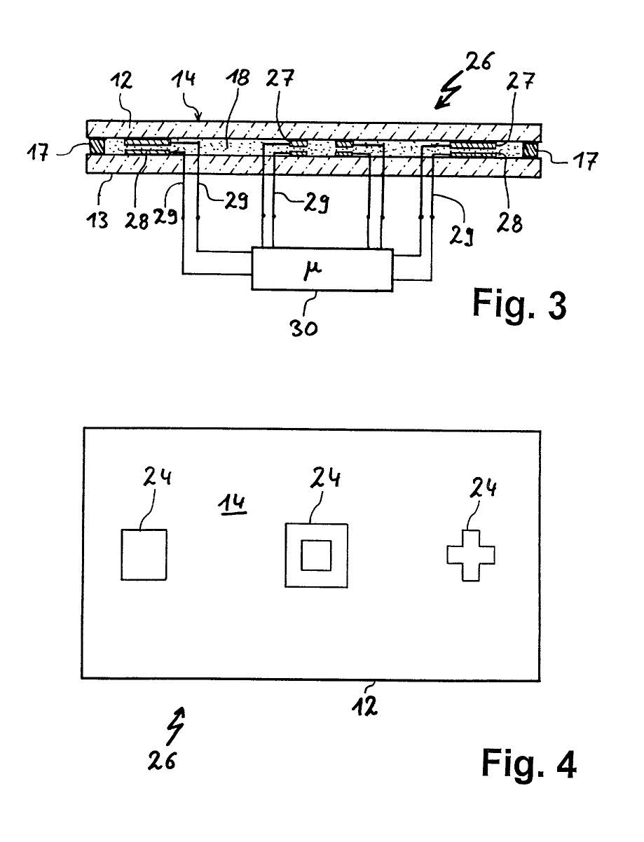

FIG. 3 shows a LCD 26 with two glass plates 12 and 13 and a liquid crystal 18. Much as shown in FIG. 1 and subdivided into portions, the two glass plates carry an upper, conductive layer 27 and a lower, conductive layer 28, whose shape can be gathered from FIG. 4. The individual portions are in each case provided with electrical terminals 29, which pass out of the LCD in much the same way as printed circuit conductors and are connected to a microprocessor 30. Thus, each of the individual layer portions can be separately activated. The guidance of the terminals 29 is not shown here. It can be gathered from FIG. 4 how the individual LCD zones 24 appear in LCD operation.

The LCD 26 is designed for interval operation of the conductive layers 27 and 28 both as a LCD and as a capacitive touch contact switch. By means of the electrical terminals 28 the individual portions of the layers 27 and 28 can be activated as a LCD. For this purpose the layers are activated in antipole manner, as in a normal LCD.

The layers can also be short-circuited by means of the terminals 29 or the zones of the upper layer 27 can be activated as capacitive touch contact switches or as a sensor surface for the same, but then no LCD symbol can be displayed. It is particularly advantageous for the two modes to be rapidly alternately performed in interval operation in such a way that ultimately both are possible. It is e.g. possible with a frequency of above 50 Hz and preferably above 70 Hz, to alternate LCD operation and touch contact switch operation. Thus, for the user the LCD symbol is permanently visible and the touch contact switch is quasi-permanently activated. In addition, it is possible to make the residence times different, e.g. longer for LCD operation than for contact switch operation.

The prerequisite for this operating mode is that the portion of the layer which becomes the sensor element is not connected to the remaining area of the layer, particularly the lower layer. Over and beyond this portion must pass no paths for the terminals 29. If one portion of a layer is operated as a sensor element and is faced by a portion of the other layer for LCD display purposes, then the two portions must be short-circuited for the duration of the sensor element function.

1. Touch contact switch having a LCD, which has two parallel, superimposed plates, between which are provided conductive layers having terminals for the display of individual segments of said LCD, wherein below a surface of said LCD is provided at least one sensor element of said touch contact switch, which is operable by contacting said surface of said LCD above said sensor element.

2. Touch contact switch according to claim 1, wherein said at least one sensor element is placed in the vicinity of said segments of said LCD.

3. Touch contact switch according to claim 2, wherein said at least one sensor element is positioned below said lower plate.

4. Touch contact switch according to claim 3, wherein said at least one sensor element is constructed separately from said lower plate and is separable.

5. Touch contact switch according to claim 1, wherein said touch contact switch has a reflected light barrier as the sensor element with a light transmitter and a light receiver.

6. Touch contact switch according to claim 5, wherein said touch contact switch and said reflected light barrier are constructed to be positioned without taking account of the arrangement of said segments or said conductive layers of said LCD.

7. Touch contact switch according to claim 1, wherein said sensor element is constructed as a capacitive sensor element.

8. Touch contact switch according to claim 7, wherein said sensor element is a flexible, conductive foam body which is located at a point of said LCD not having said segments or said conductive layer or said terminals above said sensor element.

9. Touch contact switch according to claim 7, wherein said sensor element has a conductive sensor layer between said plates of said LCD, said conductive sensor layer being, a sensor surface.

10. Touch contact switch according to claim 9, wherein said conductive sensor layer is in the plane of one of said two conductive layers of said LCD.

11. Touch contact switch according to claim 10, wherein said conductive sensor layer is in the plane of an upper layer of said two layers.

12. Touch contact switch according to claim 9, wherein said sensor layer is formed by at least one of said two conductive layers of said LCD and is electrically isolated from layer portions required for displaying said segments.

13. Touch contact switch according to claim 9, wherein said sensor layer is formed by at least one of said two conductive layers in a portion usable for segment display, said LCD being activatable in alternating operation, wherein said conductive layers are operated by means of said terminals in two operating modes:
on the one hand in antipole manner for segment display and on the other hand in short-circuited manner for said sensor element function.

14. Touch contact switch according to claim 13, wherein said conductive layers are activated with an alternating current.

15. Touch contact switch according to claim 14, wherein said alternating current has a frequency of 30 to 100 kHz for said sensor element function, the frequency of the alternation between said operating modes being at least 50 Hz.

16. Touch contact switch according to claim 2, wherein said at least one sensor element is placed in an area between two of said segments.

17. Touch contact switch according to claim 2, wherein said at least one sensor element is placed within an open segment.
